(19) United States
(12) Patent Application Publication
(10) Pub. No.: US 2007/0154026 A1
(43) Pub. Date: Jul. 5, 2007

(54) Mute circuit for eliminating noise during power off and electronic device using the same

(75) Inventors: Kuo-Ting Chiu, Taipei City (TW); Yu-Huei Cheng, Taipei City (TW); Tzu-Hui Lee, Taipei City (TW)

Correspondence Address: BACON & THOMAS, PLLC, 625 SLATERS LANE, FOURTH FLOOR, ALEXANDRIA, VA, 22314, US

(73) Assignee: Tatung Company, Taipei City (TW)

(21) Appl. No.: 11/439,275

(22) Filed: May 24, 2006

(30) Foreign Application Priority Data
Dec. 29, 2005 (TW) 094147200

(51) Int. Cl. H03B 29/00

(52) U.S. Cl. 381/71.1

(57) ABSTRACT

A mute circuit for eliminating noise during power off and an electronic device using the mute circuit are provided. The electronic device includes a power circuit, an audio processing circuit, a speaker, a micro control unit, and a mute circuit. The audio processing circuit is electrically connected to the speaker, whereby when the power circuit is on, the audio processing circuit works in a normal mode and outputs an audio signal to the speaker. When the power circuit is off, the mute circuit generates a trigger signal to a mute pin of the audio processing circuit for enabling the audio processing circuit to function in a mute mode so as to disable the speaker, and thus the speaker does not output sound during power off.

### BACKGROUND OF THE INVENTION

1. Field of the Invention

The present invention relates to a mute circuit and, more particularly, to a mute circuit used to eliminate noise during a power off, and an electronic device using the mute circuit.

2. Description of Related Art

Currently, electronic devices commonly supply different powers to different circuit modules; for example, in a media player, the IC of the media player needs 5V˜12V, but the speaker circuit of the media player needs 15V˜30V (about 5w˜10w), due to the speaker circuit needing a voltage more than other components in the media player. Therefore, a power circuit for a speaker circuit has to provide a high-farad capacitor to perform charging so as to supply power to the speaker circuit, yet because of the high-farad capacitor the discharge time of the capacitor is relatively long. Because the power circuit provides a low-farad capacitor to the IC, the discharge time of the low-farad capacitor is relatively short.

According to different capacitors, as the media player enters an off status, the power circuit for the speaker needs more time to perform the discharging. Therefore, when the power circuit for IC has already finished discharging, the IC will not send any sound signal to the speaker, but at this time, the speaker still performs discharging, so the speaker will output a noisy sound (such as pop voice).

Therefore, it is desirable to provide an improved mute circuit for eliminating noise during a power off and an electronic device using the mute circuit to mitigate and/or obviate the aforementioned problems.

### SUMMARY OF THE INVENTION

The object of the present invention is to provide a mute circuit for eliminating noise during a power off and an electronic device using the mute circuit, such that, during the power off, the mute circuit generates a trigger signal and outputs the trigger signal to a mute pin of an audio processing circuit for enabling the audio processing circuit to enter a mute mode.

In accordance with one aspect of the invention, there is provided an electronic device including a power circuit, an audio processing circuit, a speaker, a micro control unit and a mute circuit. The power circuit is provided for generating a voltage output. The audio processing circuit is electrically connected to the power circuit. The audio processing circuit includes a mute pin for setting the audio processing circuit to work in a mute mode or a normal mode. The audio processing circuit is used to output an audio signal during working in a normal mode, and when the audio processing circuit enters the mute mode, the audio processing circuit stops outputting the audio signal. The speaker is connected to the audio processing circuit for receiving the audio signal so as to amplify and output the audio signal. The micro control unit is electrically connected to the power circuit and the audio processing circuit for controlling the audio processing circuit. The mute circuit is electrically connected to the mute pin of the audio processing circuit. When being turned on, the power circuit supplies power to the mute circuit for performing charging and storing power, and as the power circuit is turned off, the mute circuit uses the power stored to generate a trigger signal and outputs the trigger signal to the mute pin of the audio processing circuit for enabling the audio processing circuit to enter the mute mode.

In accordance with another aspect of the invention, there is provided a mute circuit including a diode, a transistor and a capacitor. The diode has a positive terminal and a negative terminal. The positive terminal is electrically connected to the power circuit. The transistor has a collector, a base and an emitter. The emitter is electrically connected to the negative terminal of the diode. The base is connected to the power circuit through a first resistor. The emitter is connected to the mute pin of the audio processing circuit through a second resistor. The capacitor is electrically connected to the emitter of the transistor and the negative terminal of the diode. When being turned on, the power circuit supplies power to the capacitor for performing charging through the diode, and when the power circuit is turned off, the capacitor supplies voltage to turn on the transistor and thus the collector of the transistor outputs a voltage for enabling the mute pin of the audio processing circuit.

Other objects, advantages, and novel features of the invention will become more apparent from the following detailed description when taken in conjunction with the accompanying drawings.

### BRIEF DESCRIPTION OF THE DRAWINGS

FIG. 1 is a block diagram illustrating an embodiment of mute circuit of the present invention.

FIG. 2 is a schematic drawing showing an embodiment of a mute circuit according to the present invention.

### DETAILED DESCRIPTION OF THE PREFERRED EMBODIMENT

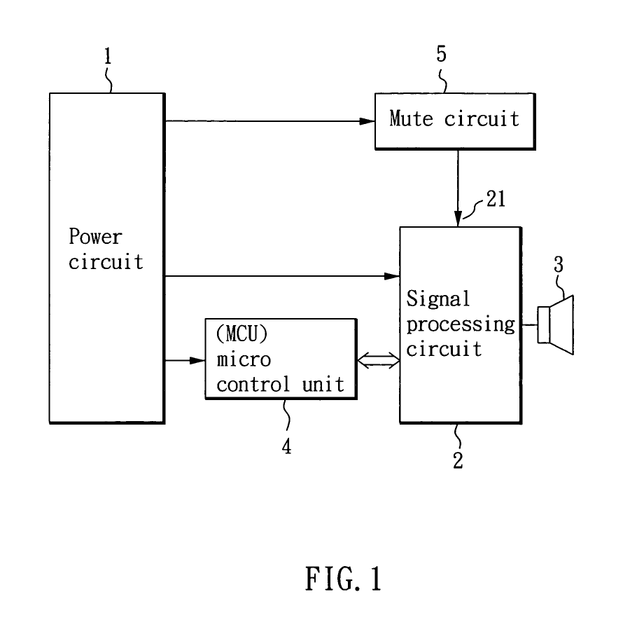

FIG. 1 shows a block diagram for a preferred embodiment of the present invention. This embodiment includes a power circuit 1, an audio processing circuit 2, a speaker 3, a micro control unit 4, and a mute circuit 5. When the electronic device is powered on, the power circuit begins to supply power to the audio processing circuit 2, the micro control unit 4, and the mute circuit 5. The micro control unit 4 is electrically connected to the audio processing circuit 2 for controlling the audio processing circuit 2. The speaker 3 is electrically connected to the audio processing circuit 2 for receiving an audio signal from the audio processing circuit so as to amplify and output the audio signal.

The aforesaid audio processing circuit 2 is a signal processing integrated chip (IC), and the audio processing circuit 2 has a mute pin 21. When the mute pin 21 receives a trigger signal from an external circuit, the audio processing circuit 2 enters a mute mode. Accordingly, by using the mute pin 21, the audio processing circuit 2 can be set in a mute mode or in a normal mode. The mute circuit 5 is electrically connected to the mute pin 21 of the audio processing circuit 2, whereby when the electronic device is powered off, the mute circuit 5 generates a trigger signal and outputs the trigger signal to the mute pin 21 of the audio processing circuit 2 for enabling the audio processing circuit 2 to enter a mute mode.

The aforesaid power circuit 1 is used to supply power to an electronic device and other circuits established in the electronic device. The micro control unit 4 is electrically connected to the power circuit 1 and the audio processing circuit 2 so as to control the audio processing circuit 2. The audio processing circuit 2 can be chosen to work in a mute mode or normal mode. When the audio processing circuit 2 works in the normal mode, the audio processing circuit 2 generates an audio signal to the speaker 3; when the audio processing circuit 2 works in a mute mode, the audio processing circuit 2 does not generate any audio signal so as to keep the speaker 3 in the mute status without generating any sound.

The aforesaid mute circuit 5 is electrically connected to the mute pin 21 of the audio processing circuit 2. When the electronic device is powered off, the power circuit 1 stops supplying power to the micro control unit 4 and the audio processing circuit 2. At this time, the mute circuit 5 generates a trigger signal and outputs the trigger signal to the mute pin 21 of the audio processing circuit 2 for enabling the audio processing circuit 5 to enter the mute mode so as to eliminate noise (Pop voice).

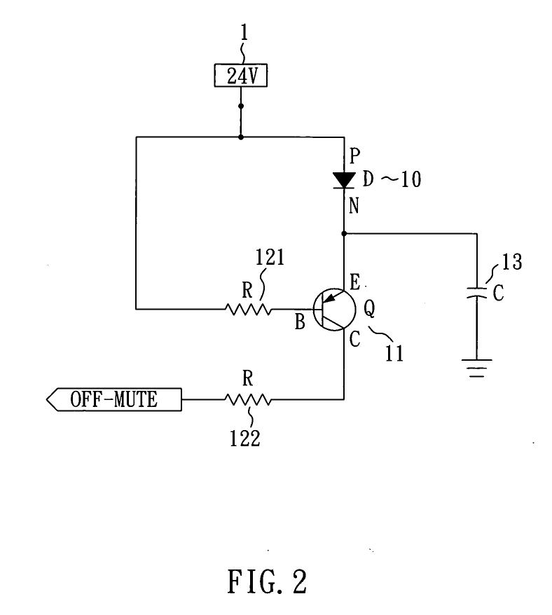

FIG. 2 shows a mute circuit for eliminating noise during the power off, wherein the mute circuit includes a diode 10, a transistor 11, a plurality of resistors, and a capacitor 13. The diode 10 has a positive terminal and a negative terminal. The positive terminal is electrically connected to the power circuit 1, and the negative terminal is electrically connected to the transistor 11. The diode 10 is used to prevent reverse current from flowing into the mute circuit 5. The transistor 11 is a PNP transistor having a collector, a base, and an emitter. The emitter is connected to the negative terminal of the diode 10. The base is connected to the power circuit 1 through a resistor 121. The emitter is connected to the mute pin 21 of the audio processing circuit 2. The capacitor 13 is electrically connected to the emitter of the transistor 11.

By using the aforesaid mute circuit, when the power circuit 1 is on, the power circuit 1 supplies power to the mute circuit; therefore, due to the voltage of the emitter being not greater than the base (0.7V), the transistor 11 is off and the voltage of the power circuit 1 is used to perform charging for storing power in capacitor 13. When the power circuit 1 is powered off, the power circuit 1 cannot supply power to the mute circuit 5. Therefore, the voltage on the base of the transistor 11 becomes 0V. Because the capacitor 13 is charged to provide a voltage, the voltage on the emitter of the transistor 11 is higher than the voltage of the base, so that the transistor 11 is turned on, and the collector of the transistor 11 outputs a voltage to the mute pin 21 of the audio processing circuit 2. In this embodiment, the voltage outputted by the collector is a trigger signal used for enabling the audio processing circuit 2 to enter the mute mode.

In view of the foregoing, it is known that the present invention uses a mute circuit to control the audio processing circuit of an electronic device so as to eliminate undesired noise. When the electronic device is powered off, the mute circuit is not shut down immediately, and the mute circuit uses the capacitor to perform charging for generating a trigger signal and outputting to the mute pin of the audio processing circuit for enabling the audio processing circuit to enter the mute mode so as to prevent the speaker from outputting noisy sound (pop voice) during power off.

Although the present invention has been explained in relation to its preferred embodiment, it is to be understood that many other possible modifications and variations can be made without departing from the scope of the invention as hereinafter claimed.

What is claimed is:

1. An electronic device for eliminating noise during power off, comprising:
a power circuit for generating a voltage output;
an audio processing circuit electrically connected to the power circuit, the audio processing circuit having a mute pin for setting the audio processing circuit to function in a mute mode or a normal mode, the audio processing circuit being used to output an audio signal during working in a normal mode, the audio processing circuit stopping outputting the audio signal when entering the mute mode;
a speaker connected to the audio processing circuit for receiving the audio signal so as to amplify and output the audio signal;
a micro control unit electrically connected to the power circuit and the audio processing circuit for controlling the audio processing circuit; and
a mute circuit electrically connected to the mute pin of the audio processing circuit;
wherein, the power circuit supplies power to the mute circuit for performing charging and storing power during power on, and when the power circuit is off, the mute circuit uses the power stored to generate a trigger signal and outputs to the mute pin of the audio processing circuit for enabling the audio processing circuit to enter the mute mode.

2. The electronic device as claimed in claim 1, wherein the mute circuit comprises:
a diode having a positive terminal and a negative terminal, the positive terminal being electrically connected to the power circuit;
a transistor having a collector, a base and an emitter, the emitter being electrically connected to the negative terminal of the diode, the base being electrically connected to the power circuit through a first resistor, the emitter being electrically connected to the mute pin of the audio processing circuit through a second resistor; and
a capacitor electrically connected to the emitter of the transistor and the negative terminal of the diode;
wherein, the power circuit supplies power to the capacitor for performing charging through the diode during power on, and as the power circuit changes to power off, the capacitor supplies voltage to the transistor, and the collector of the transistor outputs a voltage for enabling the mute pin of the audio processing circuit.

3. The electronic device as claimed in claim 2, wherein the transistor is a PNP transistor.

4. The electronic device as claimed in claim 2, wherein the audio processing circuit is a signal processing integrated chip.

5. A mute circuit for eliminating noise during power off, the mute circuit receiving power from a power circuit, and as the power circuit is turned off, the mute circuit enabling a mute pin of an audio processing circuit to make the sound process chip enter a mute mode, the mute circuit comprising
a diode having a positive terminal and a negative terminal, the positive terminal being electrically connected to the power circuit;
a transistor having a collector, a base and an emitter, the emitter being electrically connected to the negative terminal of the diode, the base being electrically connected to the power circuit through a first resistor, the emitter being electrically connected to the mute pin of the audio processing circuit through a second resistor; and
a capacitor electrically connected to the emitter of the transistor and the negative terminal of the diode;
wherein, the power circuit supplies power to the capacitor for performing charging through the diode during the power on, and when the power circuit is off, the capacitor supplies voltage to the transistor, and the collector of the transistor outputs a voltage for enabling the mute pin of the audio processing circuit.

6. The mute circuit as claimed in claim 5, wherein the transistor is a PNP transistor.
